(19) United States
(12) Patent Application Publication
(10) Pub. No.: US 2025/0372387 A1
(43) Pub. Date: Dec. 4, 2025

(54) SUBSTRATE PROCESSING APPARATUS AND SUBSTATE PROCESSING METHOD USING THE SAME

(71) Applicant: SAMSUNG ELECTRONICS CO., LTD., Suwon-si (KR)

(72) Inventors: Hyunjoong KIM, Suwon-si (KR); Sangjine Park, Suwon-si (KR)

(73) Assignee: SAMSUNG ELECTRONICS CO., LTD., Suwon-si (KR)

(21) Appl. No.: 18/967,122

(22) Filed: Dec. 3, 2024

(30) Foreign Application Priority Data
Jun. 3, 2024 (KR) 10-2024-0072400

(51) Int. Cl. H01L 21/306; H01L 21/67

(52) U.S. Cl. CPC H01L 21/30604; H01L 21/67086

(57) ABSTRACT

Provided is a substrate processing apparatus including a process body including a process space, a substrate support in the process space and configured to support a substrate, a template on the substrate support and engraved with a pattern of the substrate, a template pressurizer configured to support the template and apply a pressure to the template, and an actuator connected to the template pressurizer and configured to move the template pressurizer, wherein the actuator is further configured to move the template pressurizer in a first direction perpendicular to a first surface of the process body, a second direction and a third direction perpendicular to the first direction, and wherein the third direction is perpendicular to the second direction.

### CROSS-REFERENCE TO RELATED APPLICATION

This U.S. non-provisional patent application claims priority to Korean Patent Application No. 10-2024-0072400, filed on Jun. 3, 2024, in the Korean Intellectual Property Office, the entire contents of which are hereby incorporated by reference.

### BACKGROUND

### 1. Field

Embodiments of the present disclosure relate to a substrate processing apparatus and a substrate processing method using the same, and more specifically, relate to a substrate processing apparatus capable of controlling an etching direction of a substrate by controlling an actuator and a substrate support, and a substrate processing method using the same.

### 2. Description of Related Art

Among processes for manufacturing a semiconductor device, an etching process may include forming a semiconductor circuit pattern on a substrate by selectively removing unnecessary portions using a liquid or gas etchant. The etching process may include dry etching using a reactive gas, etc., and wet etching using a liquid such as a chemical material. In the case of the wet etching process, a surface material of the substrate may be selectively removed using a liquid, thereby lowering the process cost and relatively simplifying the process.

### SUMMARY

One or more embodiments provide a substrate processing apparatus capable of controlling an etching direction of a substrate and a substrate processing method using the same.

One or more embodiments also provide a substrate processing apparatus capable of controlling an etching rate of a substrate and uniformity and a substrate processing method using the same.

One or more embodiments also provide a substrate processing apparatus capable of maintaining a flatness of the substrate even during an etching process of a substrate and a substrate processing method using the same.

According to an aspect of one or more embodiments, there is provided a substrate processing apparatus including a process body including a process space, a substrate support in the process space and configured to support a substrate, a template on the substrate support and engraved with a pattern of the substrate, a template pressurizer configured to support the template and apply a pressure to the template, and an actuator connected to the template pressurizer and configured to move the template pressurizer, wherein the actuator is further configured to move the template pressurizer in a first direction perpendicular to a first surface of the process body, a second direction and a third direction perpendicular to the first direction, and wherein the third direction is perpendicular to the second direction.

According to another aspect of one or more embodiments, there is provided a substrate processing apparatus including a process body including a process space, a substrate support in the process space and configured to support a substrate, a template on the substrate support and engraved with a pattern of the substrate, a template pressurizer configured to support the template and apply pressure to the template, and an actuator connected to the template pressurizer and configured to move the template pressurizer, wherein the substrate support includes a substrate support body configured to support a substrate and having a plate shape, and a support body driver configured to tilt or rotate the substrate support body.

According to still another aspect of one or more embodiments, there is provided a substrate processing method, the method including supplying an etchant to a substrate processing apparatus, placing a substrate into the substrate processing apparatus, and performing a process on the substrate using the substrate processing apparatus, wherein the substrate processing apparatus includes a process body including a process space configured to store the etchant, a substrate support in the process space and configured to support the substrate, a template configured to apply a pressure to the substrate and form a pattern, a template pressurizer configured to support the template and pressurize the template, an actuator configured to move the template pressurizer and the template, and at least one processor configured to control an operation of the actuator, an operation of the template pressurizer, and an operation of the substrate support, and wherein the performing of the process on the substrate includes pressurizing the substrate by the template, and controlling the actuator by the at least one processor to change a pressure applied by the template to the substrate.

### BRIEF DESCRIPTION OF DRAWINGS

One or more embodiments will be more clearly understood from the following brief description taken in conjunction with the accompanying drawings, in which:

FIG. 1 is a perspective view showing a substrate processing apparatus according to one or more embodiments;

FIG. 2 is a cross-sectional view showing a substrate processing apparatus according to one or more embodiments;

FIG. 3 is a perspective view showing a template pressurizer according to one or more embodiments;

FIG. 4 is a plan view showing a partial pressurizer according to one or more embodiments;

FIG. 5 is a perspective view showing a substrate support according to one or more embodiments;

FIG. 6 is a perspective view showing a substrate support according to one or more embodiments;

FIG. 7 is a cross-sectional view showing a substrate support, a template, a template pressurizer, and an actuator according to one or more embodiments;

FIG. 8 is a cross-sectional view showing a substrate support, a template, a template pressurizer, and an actuator according to one or more embodiments;

FIG. 9 is a cross-sectional view showing a substrate support, a template, a template pressurizer, and an actuator according to one or more embodiments;

FIG. 10 is a cross-sectional view showing a substrate support, a template, a template pressurizer, and an actuator according to one or more embodiments; and

FIG. 11 is a flowchart showing a substrate processing method according to one or more embodiments.

### DETAILED DESCRIPTION

Hereinafter, one or more embodiments will be described with reference to the attached drawings. The same reference numerals may refer to the same elements throughout the specification.

Hereinafter, D1 may be referred to as a first direction, D2 crossing the first direction D1 may be referred to as a second direction, and D3 crossing each of the first direction D1 and the second direction D2 may be referred to as a third direction. The first direction D1 may be referred to as an upward direction, and the direction opposite to the first direction D1 may be referred to as a downward direction. Additionally, each of the second direction D2 and the third direction D3 may be referred to as a horizontal direction.

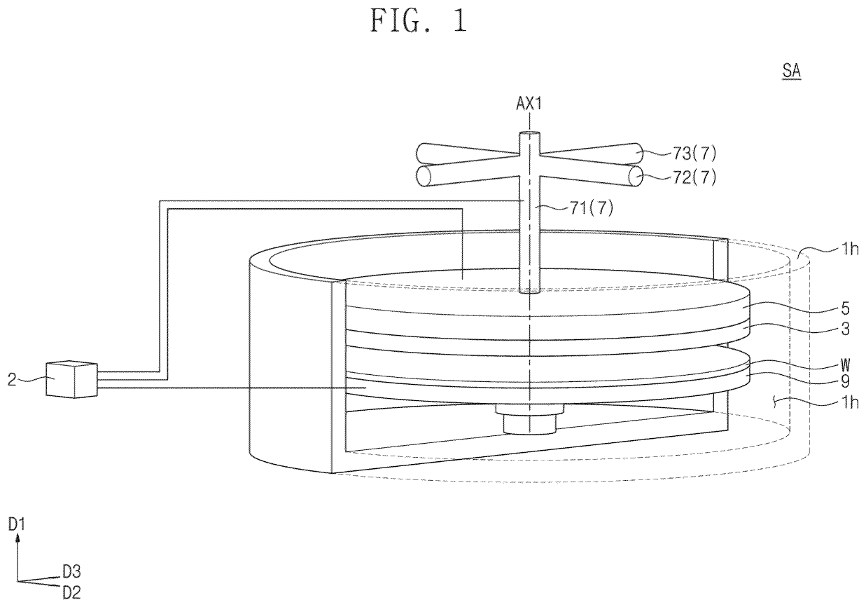

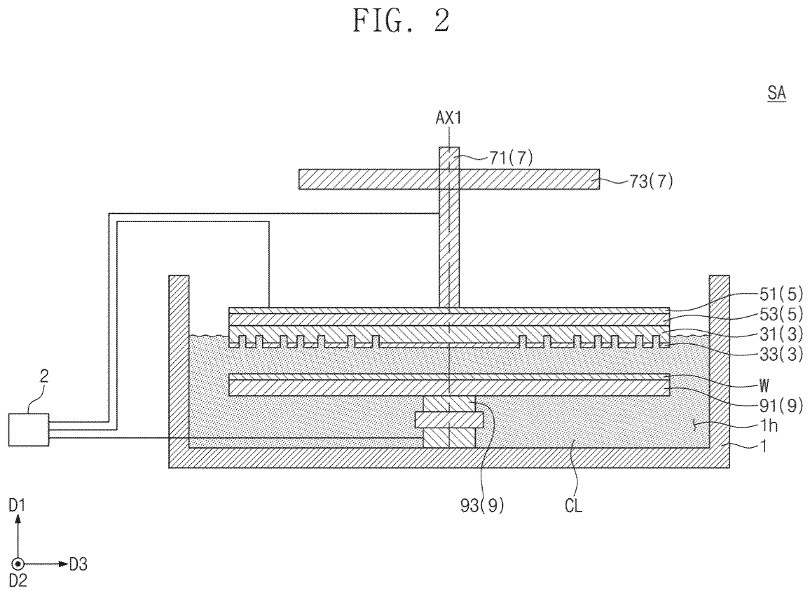

FIG. 1 is a perspective view showing a substrate processing apparatus SA according to one or more embodiments, and FIG. 2 is a cross-sectional view showing the substrate processing apparatus SA according to one or more embodiments.

The substrate processing apparatus SA may perform a process on a substrate W. According to one or more embodiments, the substrate W may include at least one of, for example, silicon (Si), germanium (Ge), gallium arsenide (GaAs), indium phosphide (InP), gallium oxide (Ga₂O₃), and silicon carbide (SiC). However, the elements contained in the substrate W are not limited thereto. More specifically, the substrate processing apparatus SA may perform a wet process on the substrate W. The wet process may be classified into a method of immersing the substrate W in an etchant CL and a method of placing the substrate W in a process chamber and spraying the etchant CL. Among the methods of etching by immersing the substrate W in an etchant CL, metal-assisted chemical etching (MACE) may refer to a method of in which oxidation and etching of the substrate W is performed using a phenomenon of holes moving through a surface of a metal catalyst layer 33 at a junction surface of the substrate W and a template 3. A via may be formed on the substrate W using the MACE method. In the present disclosure, the via may refer to a configuration that connects different metal layers of the substrate W.

The substrate processing apparatus SA may include a process body 1, a substrate support 9, a template 3, a template pressurizer 5, an actuator 7, and a controller 2. The process body 1 may provide a process space 1h. The process body 1 may have, for example, a cylindrical shape, but is not limited thereto. The process body 1 may have, as a center thereof, a first axis AX1 extending in a first direction D1. However, the shape of the process body 1 is not limited thereto. The process space 1h may be connected to an external space. The etchant CL may be stored in the process space 1h. The etchant CL may include at least one of, for example, water (H₂O), hydrogen fluoride (HF), and hydrogen peroxide (H₂O₂). However, the materials included in the etchant CL are not limited thereto, and the etchant CL may further include other types of oxidizing agents.

The template 3 may form a pattern on the substrate W. The template 3 may be positioned on substrate support 9. The template 3 may be positioned on the substrate W. The template 3 may apply pressure to the substrate W and form a pattern. Referring to FIG. 2, the template 3 may include a template body 31 and a metal catalyst layer 33. The template body 31 may support the metal catalyst layer 33. The metal catalyst layer 33 may be connected to a lower portion of the template body 31. The metal catalyst layer 33 may have a pattern engraved on the substrate W. The metal catalyst layer 33 may include a metal catalyst. The metal catalyst may include at least one of, for example, gold (Au), silver (Ag), platinum (Pt), copper (Cu), nickel (Ni), palladium (Pd), iron (Fe), aluminum (Al), and alloys thereof. However, the type of metal catalyst is not limited thereto. The metal catalyst may accelerate a reaction of the etchant CL with the substrate W.

The template pressurizer 5 may support the template 3. The template pressurizer 5 may etch the substrate W by applying pressure to the template 3. The template pressurizer 5 may be connected to an upper surface of the template 3. The template pressurizer 5 may be positioned on the template 3. The template pressurizer 5 may be positioned on the substrate support 9. Referring to FIG. 2, the template pressurizer 5 may include a pressurizing body 51 and a partial pressurizer 53. The pressurizing body 51 may support the partial pressurizer 53. The pressurizing body 51 may control the partial pressurizer 53. The pressurizing body 51 may change a pressure applied by the partial pressurizer 53 to the substrate W. A detailed description of the template pressurizer 5 will be provided below.

The actuator 7 may move the template 3 and the template pressurizer 5. The actuator 7 may be a device that changes the state of the actuator or the state of surroundings of the actuator in response to a certain signal. The actuator 7 may be, for example, an electric actuator, a hydraulic actuator, and a pneumatic actuator depending on an operation method. The actuator 7 may be connected to the template pressurizer 5. The actuator 7 may support the template pressurizer 5 and the template 3. A moving direction and moving rate of the template 3 and the template pressurizer 5 may be changed by the actuator 7. The actuator 7 may move the template 3 and the template pressurizer 5 in three-dimensional space. The actuator 7 may include a first actuator 71 extending in the first direction D1, a second actuator 72 extending in the second direction D2, and a third actuator extending 73 in the third direction D3. The first actuator 71, the second actuator 72, and the third actuator 73 may be connected to each other. The first actuator 71, the second actuator 72, and the third actuator 73 may extend perpendicular to each other. The first actuator 71, the second actuator 72, and the third actuator 73 may be linear actuators. However, embodiments are not limited thereto, and the first actuator 71, the second actuator 72, and the third actuator 73 may further include other types of actuators 7. The configuration of the actuator 7 is not limited thereto. The actuator 7 may further include a component that may be connected to the template 3 and the template pressurizer 5. The actuator 7 may further include a motor capable of changing the moving rate of the template 3 and the template pressurizer 5.

The substrate support 9 may support the substrate W. The substrate support 9 may rotate the substrate W. The substrate support 9 may be located in the process space 1h. A level of the substrate support 9 may be lower than a level of the template 3 in the first direction D1. Referring to FIG. 2, the substrate support 9 may include a substrate support body 91 and a support body driver 93. The substrate support body 91 may support the substrate W. The substrate support body 91 may have, for example, a disk plate shape. A diameter of the substrate support body 91 may be greater than or equal to about 300 mm. However, the shape of the substrate support body 91 is not limited thereto. The support body driver 93 may be coupled to the substrate support body 91. The support body driver 93 may be located below the substrate support body 91 in the first direction D1. The support body driver 93 may move the substrate support body 91, as described in detail below.

The controller 2 may be connected to the substrate support 9, the actuator 7, and the template pressurizer 5. The controller 2 may control the substrate support 9, the actuator 7, and the template pressurizer 5. An operation of the controller 2 will be described in detail below.

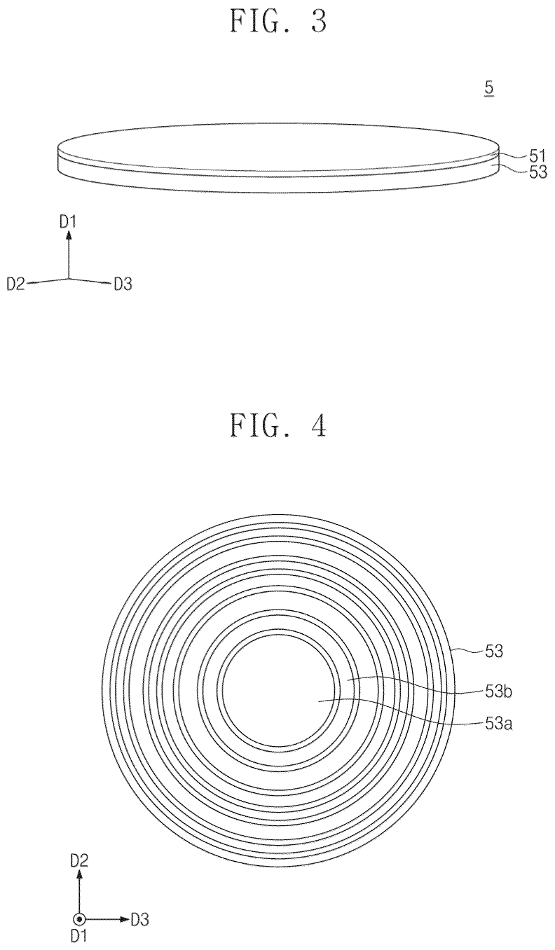

FIG. 3 is a perspective view showing the template pressurizer 5 according to one or more embodiments, and FIG. 4 is a plan view showing the template pressurizer 5 according to one or more embodiments.

Referring to FIG. 3, the template pressurizer 5 may have, for example, a disc plate shape. However, the shape of the template pressurizer 5 is not limited thereto. Referring to FIG. 4, a plurality of partial pressurizers 53 may be provided. Hereinafter, the plurality of partial pressurizers 53 may be described as singular for convenience of explanation. The partial pressurizer 53 may have a concentric shape. For example, the partial pressurizer 53 may include a first partial pressurizer 53a and a second partial pressurizer 53b. The first partial pressurizer 53a may pressurize at least a portion of the template 3. In the present disclosure, the first partial pressurizer 53a may be a partial pressurizer 53 that presses a center of the template 3. The first partial pressurizer 53a may have, for example, a circular shape to press the center of the template 3. The second partial pressurizer 53b may be connected to the first partial pressurizer 53a. The second partial pressurizer 53b may have a ring shape adjacent to and surrounding the first partial pressurizer 53a. However, the shape of the partial pressurizer 53 is not limited thereto. The partial pressurizer 53 may have a fan-shaped shape. The partial pressurizer 53 may further have various shapes for pressurizing various regions of the template 3.

The partial pressurizer 53 may include a press to apply pressure to the template 3. The press may include at least one of, for example, a crank press, a knuckle press, a friction press, and a hydraulic press. The crank press may combine a crankshaft and a connection rod to convert a rotational motion of a shaft into linear motion. In the knuckle press, a slide may move up and down by a rotation of the crank shaft, and the slide may stop for a certain period of time or move quickly in a straight line by a cam. The friction press may include two left and right disks rotating in a vertical plane, and the central disk rotating in a horizontal plane may move a ram up and down while rotating due to friction force. The hydraulic presses may include hydraulic presses and hydraulic presses. The hydraulic press may operate a hydraulic pump using an electric motor to send high-pressure fluid directly to the cylinder, allowing a slide to move in a straight line. However, the type of press is not limited thereto, and the partial pressurizer may include various types of presses for pressurizing the substrate.

Referring to FIGS. 2 and 4, the template pressurizer 5 may be controlled by the controller 2. The controller 2 may control the partial pressurizer 53 by controlling the pressurizing body 51. The controller 2 may individually control a plurality of partial pressurizers 53. The controller 2 may individually control the pressure applied to the template 3 by the first partial pressurizer 53a and the second partial pressurizer 53b. The controller 2 may maintain a flatness of the substrate W using the partial pressurizer 53. The controller 2 may individually control the pressure of the first partial pressurizer 53a and the second partial pressurizer 53b to increases the pressure of the partial pressurizer 53, which applies weak pressure to the substrate W, thereby increasing the flatness of the substrate W. For example, as the actuator 7 is located on the first partial pressurizer 53a, a region of the substrate W to which the second partial pressurizer 53b applies pressure may receive less pressure than a region of the substrate W to which the first partial pressurizer 53a applies pressure when the first partial pressurizer 53a and the second partial pressurizer 53b apply the same pressure to the substrate W. Accordingly, the controller 2 may increase the flatness of the substrate W during the etching process by setting a pressure of the second partial pressurizer 53b to be higher than a pressure of the first partial pressurizer 53a. The controller 2 may readjust a pressure of the template pressurizer 5 by receiving feedback on information about the flatness of the substrate W.

At least one of the components, elements, modules or units (collectively “components” in this paragraph) represented by a block in the drawings, such as the controller 2 in FIG. 1, may be embodied as various numbers of hardware, software and/or firmware structures that execute respective functions described above, according to an exemplary embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above exemplary embodiments may be implemented in algorithms that execute on one or more processors. Furthermore, the components represented by a block or processing steps may employ any number of related art techniques for electronics configuration, signal processing and/or control, data processing and the like.

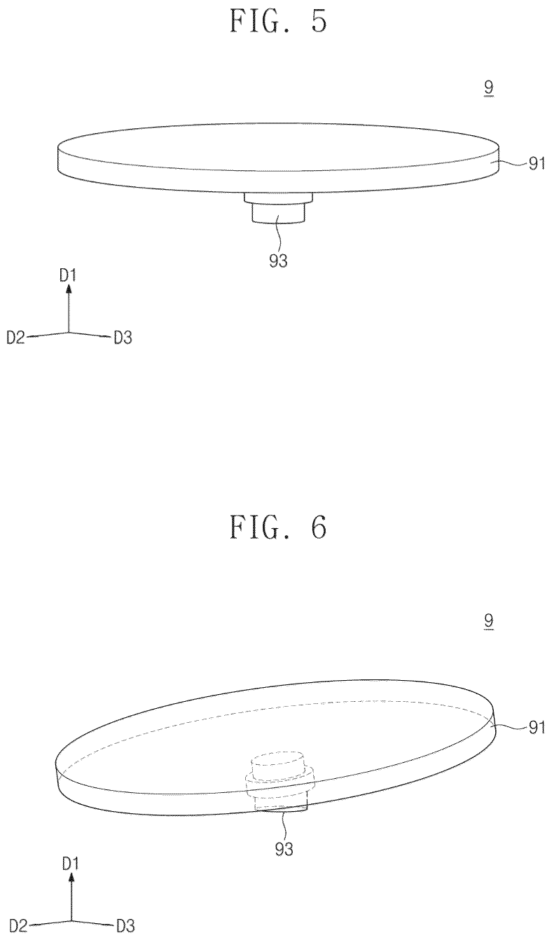

FIG. 5 is a perspective view showing the substrate support 9 according to one or more embodiments, and FIG. 6 is a perspective view showing the substrate support 9 according to one or more embodiments.

Referring to FIG. 5, the substrate support 9 may rotate the substrate W. The support body driver 93 may be rotated by a motor. As the support body driver 93 rotates, the substrate support body 91 may also rotate. Referring to FIGS. 2 and 6, the substrate support 9 may change a tilt of the substrate W. The substrate support 9 may be connected to the controller 2. The support body driver 93 may be connected to the controller 2. The controller 2 may control a rotation direction and a rotation rate of the support body driver 93. As the controller 2 controls the rotation of the support body driver 93, degree of freedom in arranging the substrate W may increase. The controller 2 may change an inclination of the substrate support body 91 by controlling the support body driver 93. As the controller 2 changes the inclination of the substrate support body 91, degree of etching for each section of the substrate may be controlled.

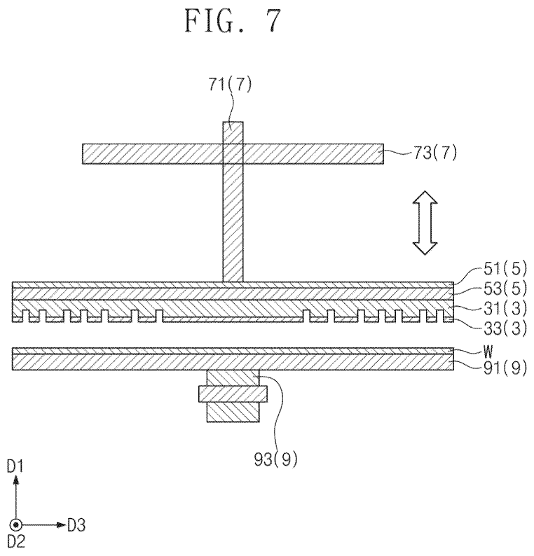

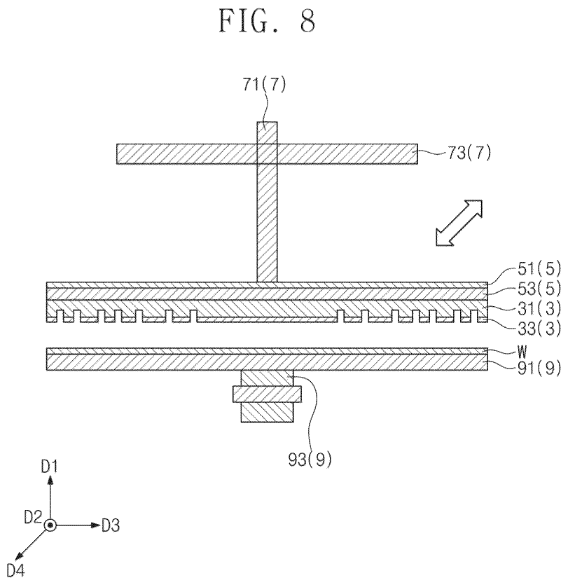

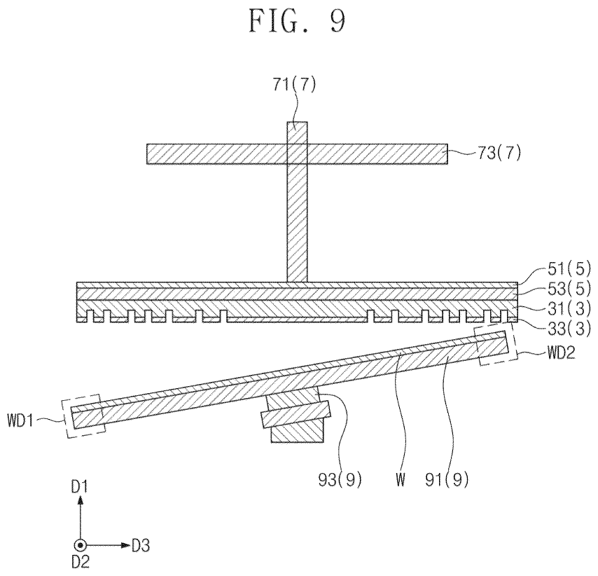

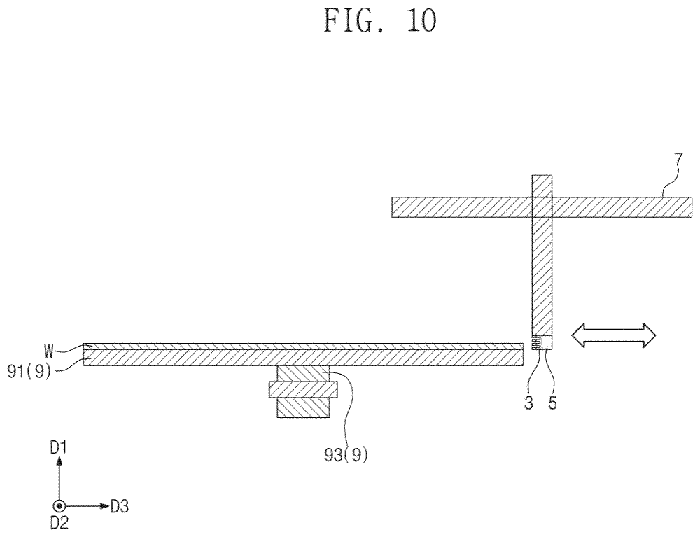

FIG. 7 is a cross-sectional view showing the substrate support 9, the template 3, the template pressurizer 5, and the actuator 7 according to one or more embodiments, FIG. 8 is a cross-sectional view showing the substrate support 9, the template 3, the template pressurizer 5, and the actuator 7 according to one or more embodiments, and FIG. 9 is a cross-sectional view showing the substrate support 9, the template 3, the template pressurizer 5, and the actuator 7 according to one or more embodiments.

Referring to FIGS. 2, 7, and 8, a substrate processing apparatus SA may include a template 3 and a template pressurizer 5 moved by an actuator 7. The actuator 7 may move the template 3 and the template pressurizer 5 in at least one of the first direction D1, the second direction D2, and the third direction D3. When the substrate W and the template 3 are in contact, the controller 2 moves the actuator 7 in at least one of the first direction D1, the second direction D2, and the third direction D3. By moving, the template 3 and the template pressurizer 5 may be pressed. The actuator 7 may control the etching rate and etching amount of the substrate W by controlling the moving direction and moving rate of the template 3. When the actuator 7 and the template pressurizer 5 increase the pressure applied to the template 3, reactivity of the metal catalyst layer 33 and the substrate W may increase. When the actuator 7 reduces the pressure applied to the template 3, reactivity of the metal catalyst layer 33 and the substrate W may decrease. When the actuator 7 separates the template 3 from the substrate W, an etching process of the substrate W may be stopped. Referring to FIG. 8, the actuator 7 may move the template 3 in two or more directions among the first direction D1, the second direction D2, and the third direction D3. In the present disclosure, the actuator 7 may move the template 3 in a fourth direction D4 including the first direction D1 and the third direction D3. When the actuator 7 moves the template 3 in the fourth direction D4, the substrate W may also be etched in the fourth direction D4. However, the etching direction of the substrate W by the actuator 7 is not limited thereto, and the actuator 7 may move the template 3 in various directions in space.

Referring to FIG. 9, a substrate support body 91, a template 3, a template pressurizer 5, and an actuator 7 that are tilted by the support body driver 93 may be provided. Referring to FIGS. 2 and 9, as the substrate support body 91 may be tilted by the support body driver 93, the controller 2 may change an etching direction of the substrate W. For example, when the substrate support body 91 is not tilted as shown in FIG. 7, an etching direction of the substrate W may be in the first direction D1. When the substrate support body 91 may be tilted as shown in FIG. 9, an etching direction of the substrate W may include the first direction D1 and the third direction D3. As the tilt of the substrate support body 91 increases, the etching direction of the substrate W may also tilt. As the substrate support body 91 may be tilted using the support body driver 93, the controller 2 may change an etching region of the substrate W. Referring to FIG. 9, the substrate W may include a first substrate region WD1 that has a long vertical distance from the template 3 and a second substrate region WD2 that has a short vertical distance from the template 3. When the template 3 moves down in the vertical direction, the template 3 may be in contact with the second substrate region WD2 but not the first substrate region WD1. In this case, the template 3 may only etch the second substrate region WD2. The template 3 may perform more etching in the second substrate region WD2 than in the first substrate region WD1.

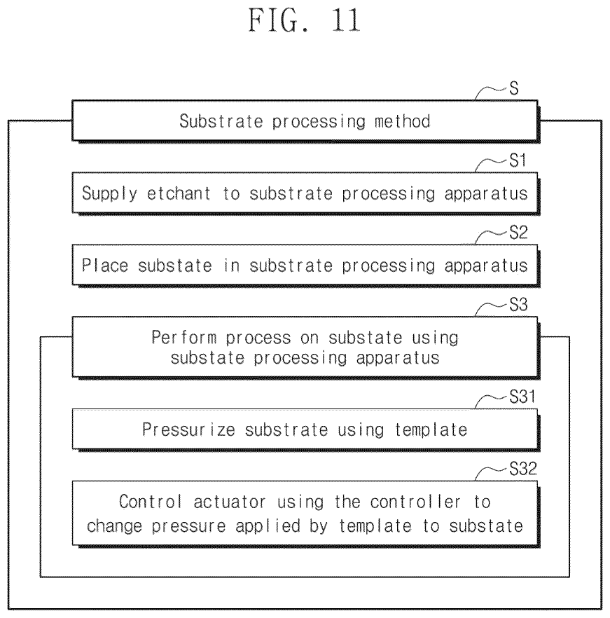

FIG. 10 is a cross-sectional view showing the substrate support 9, template 3, template pressurizer 5, and actuator 7 according to one or more embodiments.

The template 3 and the template pressurizer 5 may have various shapes other than a disc plate shape. For example, FIG. 10 may provide a substrate processing apparatus SA including a template 3 and a template pressurizer 5 capable of etching a side surface of the substrate W. The actuator 7 may move the template 3 in a horizontal direction to form a pattern or via on the side surface of the substrate W. A shape of the template 3 and the template pressurizer 5 is not limited thereto, and the template 3 and the template pressurizer 5 may have various shapes that may form various types of patterns on the substrate W.

FIG. 11 is a flowchart showing a substrate processing method S according to one or more embodiments.

Referring to FIG. 11, the substrate processing method S may include supplying an etchant CL to a substrate processing apparatus SA in S1, placing the substrate W in the substrate processing apparatus SA in S2, and performing a process on the substrate W using the substrate processing apparatus SA in S3. The performing of the process on the substrate W using the substrate processing apparatus SA in S3 may include pressurizing the substrate W using the template 3 in S31 and controlling the actuator 7 using the controller 2 to change a pressure applied by the template 3 to the substrate W in S32.

As a moving direction and a moving rate of the template 3 are changed, the actuator 7 may change an intensity and a direction of the pressure applied by the template 3 to the substrate W.

The performing of the process on the substrate W in S3 may further include individually controlling pressures of the first partial pressurizer 53a and the second partial pressurizer 53b using the controller 2.

According to the substrate processing apparatus and the substrate processing method using the same according to one or more embodiments, the etching time, rate, and direction of the substrate may be controlled by controlling the template and the substrate support. The substrate processing apparatus may include the template, the template pressurizer, the actuator, the substrate support, and the control portion. The controller may control the moving rate and moving direction of the template and the template pressurizer by controlling the actuator. The pressure applied by the template to the substrate and the etching rate of the substrate may be proportional. For example, as the pressure between the template and the substrate increases, the etching rate of the substrate may increase. The contact time between the template and the substrate may be proportional to the etching time of the substrate. For example, as the contact time of the template and the substrate increases, the etching time of the substrate may increase. When the actuator moves the template so that the substrate and the template do not come into contact, the etching process of the substrate may be stopped or terminated. The controller may control the etching amount of the substrate by controlling the etching time and etching rate of the substrate. The template pressurization device may also affect the etch rate and etch time of the substrate. When the template pressurizer increases the pressure applied to the template, the pressure applied by the template to the substrate may increase, which may increase the etching rate of the substrate. The etching direction of the substrate may also be variously changed depending on the direction in which the actuator moves the template and the template pressurizer. When the template and the substrate are in contact, the substrate may be etched depending on the direction in which the actuator moves the template and the template pressurizer.

The controller may change the etching direction, the etching region, and the etching amount of the substrate by moving the substrate support. The controller may rotate the substrate by rotating the support body driver. As the substrate rotates, the substrate processing apparatus may form different patterns for each region of the substrate. When the controller tilts the substrate support body by the support body driver, the etching direction of the substrate may be changed. When the inclination of the substrate support body increases, the etching direction of the substrate may also approach horizontal. When the controller tilts the substrate support body, the substrate may include an region in contact with the template and an region not in contact with the template. The controller may determine the etch region of the substrate using the tilt of the substrate support body.

According to the substrate processing apparatus and the substrate processing method using the same according to one or more embodiments, the flatness and etching uniformity of the substrate may be improved. The template pressurizer may include a plurality of partial pressurizers. The plurality of partial pressurizers may pressurize different regions of the substrate. The controller may individually control the plurality of partial pressurizers to apply different pressures to different regions of the substrate. The controller may control the flatness of the substrate by receiving feedback on information about the flatness of the substrate.

According to the substrate processing method of one or more embodiments and the substrate processing method using the same, the etching direction of the substrate may be controlled.

According to the substrate processing method of one or more embodiments and the substrate processing method using the same, the etching rate of the substrate and uniformity may be controlled.

According to the substrate processing method of one or more embodiments and the substrate processing method using the same, the flatness of the substrate may be maintained even during the etching process.

The effects of one or more embodiments are not limited to the effects mentioned above, and other effects not mentioned will be clearly understood by those skilled in the art from the description above.

While embodiments have been described with reference to the figures, it will be understood by those of ordinary skill in the art that various changes in form and details may be made therein without departing from the spirit and scope as defined by the following claims and their equivalents.

What is claimed is:

1. A substrate processing apparatus comprising:
a process body comprising a process space;
a substrate support in the process space and configured to support a substrate;
a template on the substrate support and engraved with a pattern of the substrate;
a template pressurizer configured to support the template and apply a pressure to the template; and
an actuator connected to the template pressurizer and configured to move the template pressurizer,
wherein the actuator is further configured to move the template pressurizer in a first direction perpendicular to a first surface of the process body, a second direction and a third direction perpendicular to the first direction, and
wherein the third direction is perpendicular to the second direction.

2. The substrate processing apparatus of claim 1, further comprising at least one processor configured to control the template pressurizer and the actuator,
wherein the at least one processor is further configured to control a moving direction and a moving distance of the actuator.

3. The substrate processing apparatus of claim 2, wherein the at least one processor is further configured to move the template pressurizer in at least one of the first direction, the second direction, and the third direction using the actuator.

4. The substrate processing apparatus of claim 1, wherein the template pressurizer comprises:
a first partial pressurizer configured to pressurize at least a portion of the template; and
a second partial pressurizer connected to the first partial pressurizer.

5. The substrate processing apparatus of claim 4, wherein the first partial pressurizer and the second partial pressurizer comprise a hydraulic device.

6. The substrate processing apparatus of claim 4, further comprising at least one processor configured to control the template pressurizer and the actuator,
wherein the at least one processor is further configured to individually control the first partial pressurizer and the second partial pressurizer.

7. The substrate processing apparatus of claim 1, wherein the substrate support comprises:
a substrate support body configured to support the substrate; and
a support body driver connected to the substrate support body and configured to rotate the substrate support body or tilt the substrate support body.

8. The substrate processing apparatus of claim 7, further comprising at least one processor configured to control the substrate support body,
wherein the at least one processor is further configured to control an rotation angle and a tilt of the substrate support body.

9. The substrate processing apparatus of claim 1, wherein the template comprises a metal catalyst layer engraved with a pattern to be formed on the substrate,
wherein the metal catalyst layer comprises at least one of gold (Au), silver (Ag), platinum (Pt), copper (Cu), nickel (Ni), palladium (Pd), iron (Fe), aluminum (Al), and alloys thereof, and
wherein the metal catalyst layer is at the lowermost end of the template.

10. A substrate processing apparatus comprising:
a process body comprising a process space;
a substrate support in the process space and configured to support a substrate;
a template on the substrate support and engraved with a pattern of the substrate;
a template pressurizer configured to support the template and apply pressure to the template; and
an actuator connected to the template pressurizer and configured to move the template pressurizer,
wherein the substrate support comprises:
a substrate support body configured to support a substrate and having a plate shape; and
a support body driver configured to tilt or rotate the substrate support body.

11. The substrate processing apparatus of claim 10, further comprising at least one processor configured to control the substrate support,
wherein the at least one processor is further configured to control tilt and rotation of the substrate support body by controlling the support body driver.

12. The substrate processing apparatus of claim 11, wherein the at least one processor is further configured to control a degree of inclination and rotation of the substrate support body depending on an etching amount of the substrate.

13. The substrate processing apparatus of claim 10, wherein the process body comprises a first surface perpendicular to a first axis extending in a first direction,
wherein the first direction is perpendicular to second and third directions,
wherein the second direction and the third direction are perpendicular,
wherein the actuator is configured to move the template pressurizer in at least one of the first direction, the second direction, and the third direction.

14. The substrate processing apparatus of claim 13, further comprising at least one processor configured to control the actuator,
wherein the at least one processor is further configured to control movement of the template by controlling the movement of the actuator.

15. The substrate processing apparatus of claim 10, wherein the template pressurizer comprises:
a first partial pressurizer configured to pressurize a center of the template; and
a second partial pressurizer adjacent to the first partial pressurizer.

16. The substrate processing apparatus of claim 15, further comprising at least one processor configured to control a pressure of the template pressurizer,
wherein the at least one processor is further configured to individually control pressure of the first partial pressurizer and the second partial pressurizer.

17. A substrate processing method, the method comprising:
supplying an etchant to a substrate processing apparatus;
placing a substrate into the substrate processing apparatus; and
performing a process on the substrate using the substrate processing apparatus,
wherein the substrate processing apparatus comprises:
a process body comprising a process space configured to store the etchant;
a substrate support in the process space and configured to support the substrate;
a template configured to apply a pressure to the substrate and form a pattern;
a template pressurizer configured to support the template and pressurize the template;
an actuator configured to move the template pressurizer and the template; and
at least one processor configured to control an operation of the actuator, an operation of the template pressurizer, and an operation of the substrate support, and
wherein the performing of the process on the substrate comprises:
pressurizing the substrate by the template; and
controlling the actuator by the at least one processor to change a pressure applied by the template to the substrate.

18. The method of claim 17, wherein the etchant comprises at least one of hydrogen fluoride (HF), hydrogen peroxide (H₂O₂), water (H₂O), and a mixed solution thereof.

19. The method of claim 17, wherein the template pressurizer comprises:
a first partial pressurizer connected to the template; and
a second partial pressurizer connected to the first partial pressurizer and the template, and
wherein the performing of the process on the substrate further comprises individually controlling a pressure of the first partial pressurizer and the second partial pressurizer by the at least one processor.

20. The method of claim 17, wherein the substrate support comprises:
a substrate support body having a plate shape; and
a support body driver configured to change a rotation and a tilt of the support body, and
wherein the performing of the process on the substrate comprises changing a rotation and a tilt of the substrate support body by the support body driver in the at least one processor.
